(19) United States
(12) Patent Application Publication
(10) Pub. No.: US 2026/0059718 A1
(43) Pub. Date: Feb. 26, 2026

(54) SYSTEMS AND METHODS FOR WATER COOLED PRE-SYSTEM

(71) Applicant: Vertiv Corporation, Westerville, OH (US)

(72) Inventor: Phillip Wayne Spiegel, Delaware, OH (US)

(21) Appl. No.: 19/308,671

(22) Filed: Aug. 25, 2025

Related U.S. Application Data
(60) Provisional application No. 63/687,075, filed on Aug. 26, 2024.

(51) Int. Cl. H05K 7/20

(52) U.S. Cl. CPC H05K 7/20827

(57) ABSTRACT

A system for data center cooling includes: a first cooling unit configured to circulate refrigerant; a second cooling unit configured to circulate coolant; and a heat exchanger system in fluid communication with the first cooling unit and the second cooling unit, the heat exchanger system being configured to exchange heat between the refrigerant and the coolant.

### CROSS REFERENCE TO RELATED APPLICATIONS

This U.S. Non-Provisional patent applications claims the benefit of and priority to U.S. Provisional Patent Application Ser. No. 63/687,075 filed Aug. 26, 2024, the contents of which are incorporated herein by reference in its entirety.

### TECHNICAL FIELD

This disclosure relates to device cooling systems, and, in particular, to systems and methods for a water cooled pre-system.

### BACKGROUND

A data hall may comprise various processing units and/or computing systems that generate heat. Accordingly, cooling such processing units and/or computing systems is critically important to avoid overheating, which may result in damage or reduced useful life of the processing units and/or computing systems. Space in data halls is typically limited, given the tightly packed configurations of such data halls. As such, cooling such processing units and/or computing systems of a data hall is bounded by space requirements and the need for efficient use of the space, while continuing to provide adequate cooling.

### SUMMARY

An aspect of the disclosed embodiment includes a system for a water cooled pre-system for data halls. The system includes a condenser assembly configured to direct a flow of water to one or more processing units using one or more rods of a heat exchanger assembly.

Another aspect of the disclosed embodiments includes a system for a water cooled pre-system for data halls. The system includes: a heat exchanger system disposed in a cabinet and configured to direct a flow of water to one or more processing units using one or more rods; an outdoor heat exchanger disposed outside of a building associated with the cabinet, the outdoor heat exchanger being configured to communicate with the heat exchanger; and a fluid tank disposed outside of the cabinet and configured to communicate with the heat exchanger.

Another aspect of the disclosed embodiments includes a system for a water-cooled pre-system for data halls. The system includes: an outdoor unit disposed outside a building and configured to circulate refrigerant; an indoor unit disposed inside the building and configured to circulate coolant; a heat exchanger system having one or more rods in a cabinet and fluidically communicating with the outdoor unit and indoor unit, the heat exchanger system configured to receive coolant from the indoor unit through a first path of each of the one or more rods and to receive refrigerant through a second path of each of the one or more rods for heat exchange between coolant and refrigerant; a fluid tank disposed outside of the cabinet and configured to communicate with the heat exchanger; and a pump configured to circulate coolant.

Another aspect of the disclosed embodiments includes a system for data center cooling. The system includes: a first cooling unit configured to circulate refrigerant; a second cooling unit configured to circulate coolant; and a heat exchanger system in fluid communication with the first cooling unit and the second cooling unit, the heat exchanger system being configured to exchange heat between the refrigerant and the coolant.

Another aspect of the disclosed embodiments includes a heat exchanger that includes a housing configured to house one or more rods. Each of the one or more rods includes: a first path configured to receive coolant from a first cooling unit; and a second path configured to receive refrigerant from a second cooling unit, each of the one or more rods being configured to exchange heat between the refrigerant and the coolant.

### BRIEF DESCRIPTION OF THE DRAWINGS

The above and/or other aspects will become apparent and more readily appreciated from the following description of example embodiments, taken in conjunction with the accompanying drawings, in which:

FIG. 1 generally illustrates a data hall, according to the principles of the present disclosure.

FIGS. 2-4 generally illustrate a water cooled pre-system, according to the principles of the present disclosure.

### DETAILED DESCRIPTION

Reference will now be made in detail to example embodiments which are illustrated in the accompanying drawings, wherein like reference numerals refer to like elements throughout. In this regard, the example embodiments may have different forms and may not be construed as being limited to the descriptions set forth herein.

It will be understood that the terms “include,” “including,” “comprise,” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be further understood that, although the terms “first,” “second,” “third,” etc., may be used herein to describe various elements, components, regions, layers and/or sections, these elements, components, regions, layers and/or sections may not be limited by these terms. These terms are only used to distinguish one element, component, region, layer or section from another element, component, region, layer or section.

As used herein, the term “and/or” includes any and all combinations of one or more of the associated listed items. Expressions such as “at least one of,” when preceding a list of elements, modify the entire list of elements and do not modify the individual elements of the list.

Various terms are used to refer to particular system components. Different companies may refer to a component by different names—this document does not intend to distinguish between components that differ in name but not function.

Matters of these example embodiments that are obvious to those of ordinary skill in the technical field to which these example embodiments pertain may not be described herein in detail.

It may be understood that the example embodiments described herein may be considered in a descriptive sense only and not for purposes of limitation. Descriptions of features or aspects within each example embodiment may be considered as available for other similar features or aspects in other example embodiments.

As described, a data hall may comprise various processing units and/or computing systems that generate heat. Accordingly, cooling such processing units and/or computing systems is critically important to avoid overheating, which may result in damage or reduced useful life of the processing units and/or computing systems. Space in data halls is typically limited, given the tightly packed configurations of such data halls. As such, cooling such processing units and/or computing systems of a data hall is bounded by space requirements and the need for efficient use of the space, while continuing to provide adequate cooling.

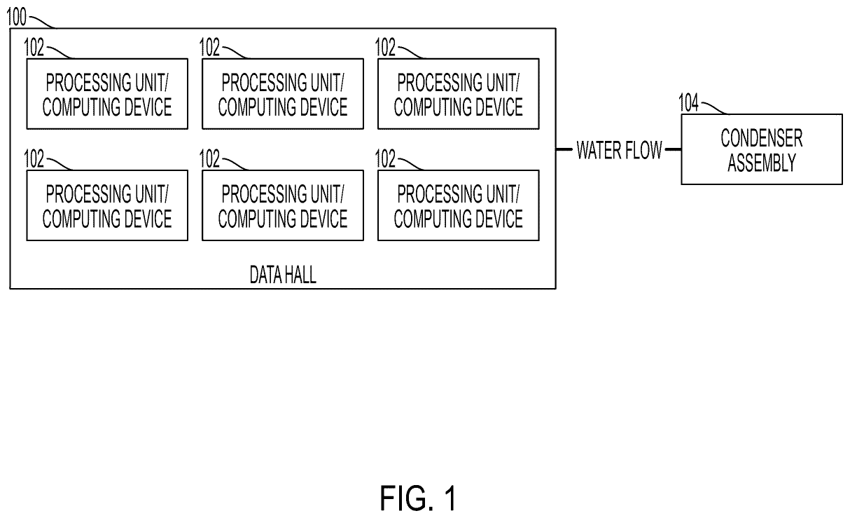

Accordingly, systems and methods, such as the systems and methods described herein, configured to provide a water cooled pre-system for data halls, may be desirable. With reference to FIG. 1, in some embodiments, the systems and methods described herein may be configured to remove heat using water while keeping refrigerant outside of a data hall 100. The data hall 100 may include various processing units/computing systems 102. A condenser assembly 104 may be configured to direct cold water to the data hall to provide cooling of the various processing units/computing systems 102. The condenser assembly 104 may be associated with various products including, but not limited to, DP400 and DO 500 products.

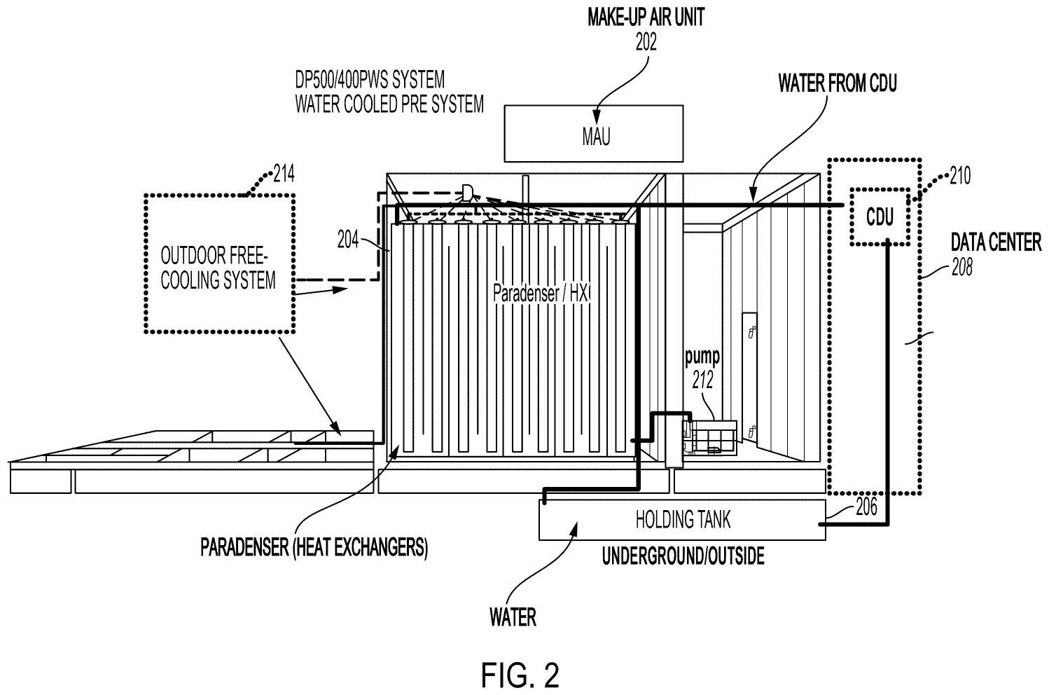

As is generally illustrated in FIGS. 2-4, the systems and methods described herein may be configured to use or provide a heat exchanger system 204 (referred to as paradenser/HX in FIG. 2) configured to provide cooling features, while being configured to withstand cleaning and other maintenance. The system 204, which may be also called a “paradenser,” is described in U.S. Ser. No. 12/262,259, the contents of which are incorporated herein by reference in their entirety. The system 204 may include a series of condensers or heat exchangers as illustrated in FIGS. 2-4.

In some embodiments, paradensers of the system 204 may be configured as tubes and include two or more fluid paths within each tube. For example, one path may include a refrigerant path and the other path may include a water flow path. The two paths may be used for heat exchange. The tubes and/or the system 204 may be disposed in a cabinet or housing within a data center 208. The data center 208 may include the data hall 100 and/or include features similar to those of the data hall 100.

The system 204 may be configured to move cold water (e.g., water at a temperature below a threshold temperature) directly to information technology (IT) loads (e.g., associated with various processing units and/or computing systems 102) of the data hall 100 that generate heat and, accordingly, are cooled by the cold water. A make-up air unit (MAU) 202 may be configured to condition air flowing into an area surrounding the system 204.

The system 204 may use existing condenser assemblies 104 to direct the flow of the cold water. In some embodiments, the system 204 may allow water to flow from a coolant distribution unit (CDU) 210 of a data center 208 to the heat exchanger of the system 204 (e.g., with hot water from the servers of the data center exchanging the heat with refrigerant) to a holding tank 206 via a pump 212 and back to the CDU 210. The holding tank 206 may be located underground or external to the data center 208 (e.g., outside of the building).

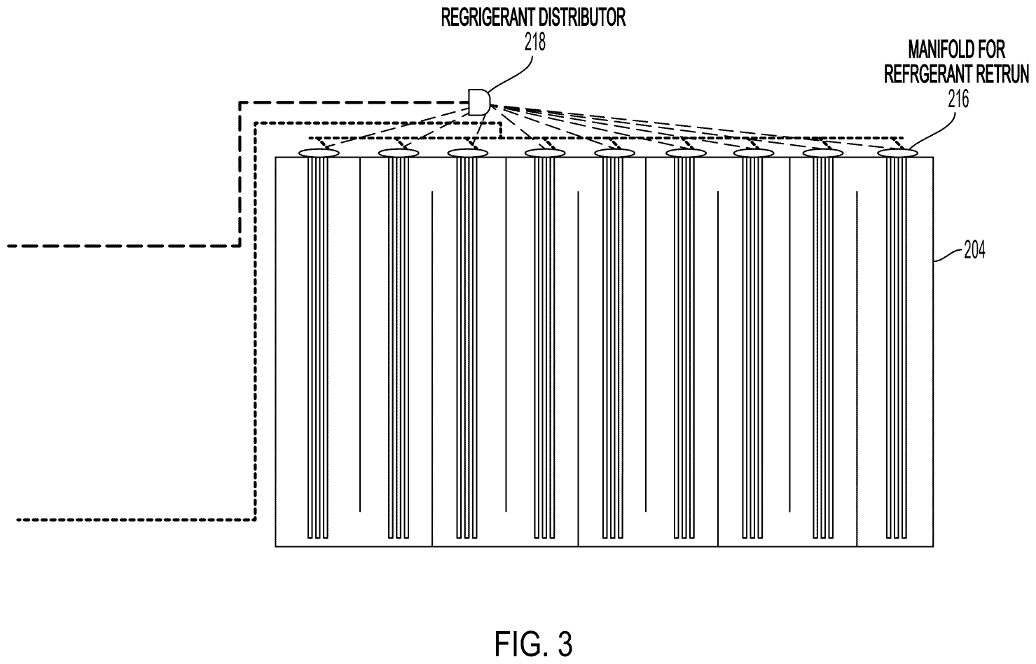

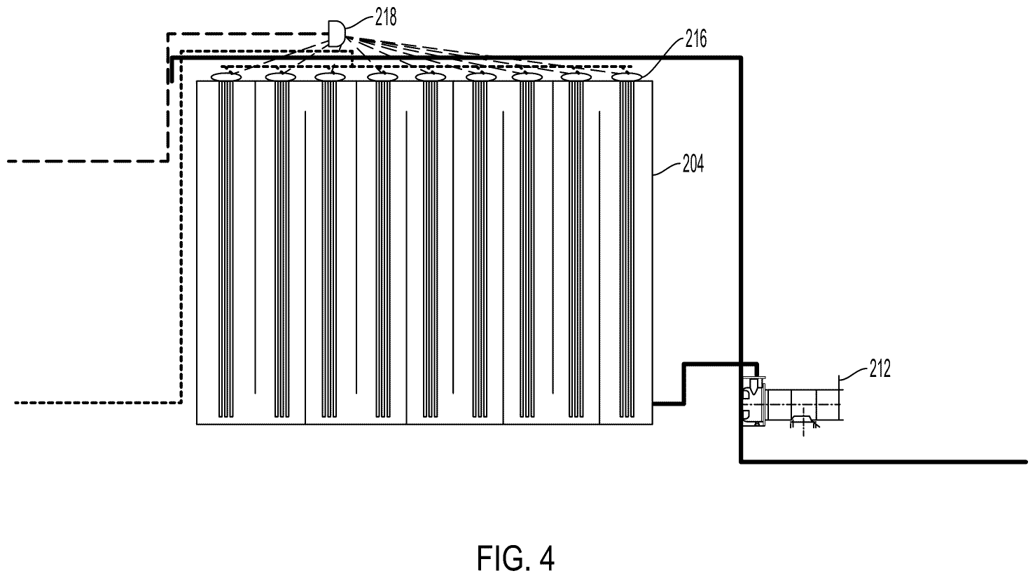

Additionally, or alternatively, the system 204 may be configured to allow refrigerant to flow from an outdoor free-cooling system 214 (e.g., Liebert DSE or DP500) via a first path via a refrigerant distributor 218 (e.g., as is generally illustrated in FIGS. 3 and 4) to the system 204, back to the free-cooling system 214 via a second path via a manifold 216 for refrigerant return as vapor (e.g., from heat exchanging with water inside the paradensers of the system 204).

The system 204 may be configured to direct the flow of cold water through heat exchangers (e.g., which may also be referred to as condenser coils, coils, and/or the like). The system 204 may be configured to use existing rods inside of the system 204. The system 204 may be configured to provide direct-to-chip cooling of IT loads and/or artificial intelligence (AI) loads.

In some embodiments, a system for a water cooled pre-system for data halls includes a condenser assembly configured to direct a flow of water to one or more processing units using one or more rods of a heat exchanger assembly.

In some embodiments, a system for data center cooling includes: a first cooling unit configured to circulate refrigerant; a second cooling unit configured to circulate coolant; and a heat exchanger system in fluid communication with the first cooling unit and the second cooling unit, the heat exchanger system being configured to exchange heat between the refrigerant and the coolant.

In some embodiments, the first cooling unit is located within a building that includes the heat exchanger system. In some embodiments, the first cooling unit is in fluid communication with a holding tank. In some embodiments, the holding tank is located outside of the building that includes the heat exchanger system. In some embodiments, the holding tank is disposed underground. In some embodiments, the second cooling unit is located outside of a building that includes the heat exchanger system. In some embodiments, the heat exchanger system includes one or more rods. In some embodiments, each rod of the one or more rods includes a first path and a second path. In some embodiments, the first path of each rod of the one or more rods is configured to receive coolant, from the first cooling unit. In some embodiments, the second path of each rod of the one or more rods is configured to receive refrigerant from the second cooling unit. In some embodiments, wherein the system also includes a pump configured to circulate the coolant of the first cooling unit. In some embodiments, the data center is associated with information technology computing devices. In some embodiments, the data center is associated with artificial intelligence computing devices.

In some embodiments, a heat exchanger includes a housing configured to house one or more rods. Each of the one or more rods includes: a first path configured to receive coolant from a first cooling unit; and a second path configured to receive refrigerant from a second cooling unit, each of the one or more rods being configured to exchange heat between the refrigerant and the coolant.

In some embodiments, the first cooling unit is located within a building that includes the housing. In some embodiments, the first cooling unit is in fluid communication with a holding tank. In some embodiments, the holding tank is located outside of the building. In some embodiments, the holding tank is disposed underground. In some embodiments, the second cooling unit is located outside of a building that includes the housing. In some embodiments, a pump, located within a building that includes the housing, is configured to circulate coolant.

In some embodiments, a system for a water cooled pre-system for data halls includes: a heat exchanger system disposed in a cabinet and configured to direct a flow of water to one or more processing units using one or more rods; an outdoor heat exchanger disposed outside of a building associated with the cabinet, the outdoor heat exchanger being configured to communicate with the heat exchanger; and a fluid tank disposed outside of the cabinet and configured to communicate with the heat exchanger.

While example embodiments have been described with reference to the figures, it will be understood by those of ordinary skill in the art that various changes in form and details may be made therein without departing from the spirit and scope as defined by the following claims.

What is claimed is:

1. A system for data center cooling, the system comprising:
a first cooling unit configured to circulate refrigerant;
a second cooling unit configured to circulate coolant; and
a heat exchanger system in fluid communication with the first cooling unit and the second cooling unit, the heat exchanger system being configured to exchange heat between the refrigerant and the coolant, wherein the refrigerant is circulated via one of a first path of a plurality of first paths and a second path of a plurality of second paths and the coolant is circulated via the other of the first path of the plurality of first paths and the second path of the plurality of second paths.

2. The system of claim 1, wherein the first cooling unit is located within a building that includes the heat exchanger system.

3. The system of claim 2, wherein the first cooling unit is in fluid communication with a holding tank.

4. The system of claim 3, wherein the holding tank is located outside of the building that includes the heat exchanger system.

5. The system of claim 3, wherein the holding tank is disposed underground.

6. The system of claim 1, wherein the second cooling unit is located outside of a building that includes the heat exchanger system.

7. The system of claim 1, wherein the heat exchanger system includes one or more rods.

8. The system of claim 7, wherein each rod of the one or more rods includes a respective first path of the plurality of first paths and a respective second path of the plurality of second paths.

9. The system of claim 8, wherein the respective first path of each rod of the one or more rods is configured to receive the coolant, from the first cooling unit.

10. The system of claim 8, wherein the respective second path of each rod of the one or more rods is configured to receive the refrigerant from the second cooling unit.

11. The system of claim 1, further comprising a pump configured to circulate the coolant of the first cooling unit.

12. The system of claim 1, wherein the data center is associated with information technology computing devices.

13. The system of claim 1, wherein the data center is associated with artificial intelligence computing devices.

14. A heat exchanger comprising:
a housing configured to house one or more rods, wherein each of the one or more rods includes:
a first path configured to receive coolant from a first cooling unit; and
a second path configured to receive refrigerant from a second cooling unit, each of the one or more rods being configured to exchange heat between the refrigerant and the coolant.

15. The heat exchanger of claim 14, wherein the first cooling unit is located within a building that includes the housing.

16. The heat exchanger of claim 15, wherein the first cooling unit is in fluid communication with a holding tank.

17. The heat exchanger of claim 16, wherein the holding tank is located outside of the building.

18. The heat exchanger of claim 16, wherein the holding tank is disposed underground.

19. The heat exchanger of claim 14, wherein the second cooling unit is located outside of a building that includes the housing.

20. The heat exchanger of claim 14, wherein a pump, located within a building that includes the housing, is configured to circulate coolant.
